(19) United States
(12) Patent Application Publication
(10) Pub. No.: US 2017/0110344 A1
(43) Pub. Date: Apr. 20, 2017

(54) WET ETCHING APPARATUS

(71) Applicant: BOE TECHNOLOGY GROUP CO., LTD., Beijing (CN)

(72) Inventor: Dapeng Xue, Beijing (CN)

(21) Appl. No.: 14/906,866

(22) PCT Filed: Aug. 14, 2015
(86) PCT No.: PCT/CN2015/087022

§ 371 Date: Jan. 21, 2016

(30) Foreign Application Priority Data
Mar. 12, 2015 (CN) 201510107896.8

(51) Int. Cl. H01L 21/67

(52) U.S. Cl. CPC H01L 21/6708; H01L 21/67023; H01L 21/30604

(57) ABSTRACT

The present invention provides a wet etching apparatus. The wet etching apparatus comprises: an etching chamber, comprising an etching chamber inlet at a front end and an etching chamber outlet at a rear end, wherein in the etching chamber, a film to be etched on a substrate is subject to etching with an etching liquid; and a decrystallization device, which washes residual etching liquid or etching liquid crystal formed by the etching liquid at the etching chamber inlet and/or etching chamber outlet with a washing liquid. By means of the decrystallization device, residual etching liquid or etching liquid crystal formed by the etching liquid at the etching chamber inlet and the etching chamber outlet can be effectively removed, thus improving operation ratio and cleanness of the apparatus as well as quality of products.

### FIELD OF THE INVENTION

The present invention relates to the filed of microelectronics processing apparatus technology, and particularly to a wet etching apparatus.

### BACKGROUND OF THE INVENTION

Currently, in the technology of flat panel display (FPD), a liquid crystal display (LCD) has gradually replaced cathode ray tube (CRT) and become a mainstream display due to its advantages of being thin, light and short, thus saving the room for placing. In various kinds of LCDs, a thin film transistor-liquid crystal display (TFT-LCD) has advantages of excellent performance and being suitable for large-scale automated production, and has become a mainstream LCD product.

In a process for fabricating a TFT-LCD, indium tin oxide (ITO) has been widely used to form a transparent display electrode, due to its excellent property. During a process for fabricating a transparent display electrode with ITO, an ITO film is firstly formed by magnetron sputtering, a pattern of photoresist is then formed by photolithography, and a pattern of ITO film is finally formed by wet etching to form the final transparent display electrode.

FIG. 1 is a structural view of a wet etching apparatus for patterning an ITO film in the prior art. Referring to FIG. 1, a substrate, a surface of which is covered by an ITO film is introduced through an inlet unit (IN CV), and organic matter on the surface is removed in a washing chamber (EUV). The substrate then enters a transition unit (NEU), and enters an etching chamber (ETCH) through a front buffer chamber (BUF1). In the etching chamber, the ITO film on the substrate which is not need any more (i.e., the ITO film not covered by the pattern of photoresist) is removed by an etching liquid. Subsequently, the substrate leaves through a rear buffer chamber (BUF2), and is washed in a first water rinsing unit (SWR1), a second water rinsing unit (SWR2), a third water rinsing unit (SWR3), a fourth water rinsing unit (SWR4), and a final water rinsing unit (FR), so that residual etching liquid on the substrate surface is removed. Then, the substrate is dried in an air knife unit (AK), and finally is transferred out of the wet etching apparatus by a transfer unit (NT) and an outlet unit (OUT CV).

FIG. 2A is a top view of an etching chamber (ETCH) and a front and rear buffer chamber (BUF1, BUF2) in a wet etching apparatus shown in FIG. 1. FIG. 2B is a side view of an etching chamber (ETCH) and a front and rear buffer chamber (BUF1, BUF2) in a wet etching apparatus shown in FIG. 1. As shown in FIG. 2A and FIG. 2B, buffer chambers, i.e., a front buffer chamber 100 and a rear buffer chamber 300, is arranged in front of and behind an etching chamber 200. Delivery wheels (101, 201, 301, or the like) transfer a substrate 400 from the front buffer chamber 100 to the etching chamber 200 for etching, and then transfers the substrate after etching from the etching chamber 200 to the rear buffer chamber 300.

A front shutter 203 is installed in the front buffer chamber 100 at a position close to an etching chamber inlet of the etching chamber 200. A shaft 203a is installed at a lower portion of the front shutter 203. The shaft 203a is connected with a cylinder. Through up and down movement of the cylinder, the shaft can drive the front shutter to turn up and down to open and close. Before the substrate 400 enters the etching chamber 200 from the front buffer chamber 100, the front shutter 203 is opened. After the substrate 400 completely enters the etching chamber 200, the front shutter 203 is closed.

Similarly, a rear shutter 204 is installed in the rear buffer chamber 300 at a position close to an outlet of the etching chamber 200. The rear shutter 204 has a same structure and operating manner as that of the front shutter 203. A shaft 204a is installed at a lower portion of the rear shutter 204. Before the substrate 400 enters the rear buffer chamber 300, the rear shutter 204 is opened. After the substrate 400 completely enters the rear buffer chamber 300, the rear shutter 204 is closed.

As can be seen, apart from the time when the substrate enters and leaves, the etching chamber 200 keeps relatively closed, so as to create a stable etching environment for etching the substrate.

The substrate is generally etched in a spraying mode, i.e., an etching liquid spraying device 202 sprays an etching liquid to an underlying substrate, so that an ITO film which is not covered by a pattern of photoresist is removed. Oxalic acid (also referred to as ethanedioic acid) has been widely applied in wet etching of ITO, since it has a low cost and can fully satisfy requirements in the whole process for TFT substrate. In the process for TFT substrate, oxalic acid for wet etching of ITO is generally an aqueous solution with a concentration of 3.4%˜3.8%, and temperature during the process is 40° C.˜45° C. However, oxalic acid has such a feature that when oxalic acid cools, it is prone to form white crystal. The white crystal is soluble in water.

During wet etching of ITO, the front shutter 203 and the rear shutter 204 open and close repeatedly, and oxalic acid in the etching chamber 200 may volatilize from the front and rear shutters in an opened state. Since both the front and rear buffer chambers have a temperature lower than that of the etching chamber, oxalic acid turns into crystal at a lower temperature, and a large amount of crystal 601 forms at the inlet, the front shutter, the outlet, and the rear shutter of the etching chamber, as shown in FIG. 3. After a long time, crystal 601 of oxalic acid may completely cover the inlet and outlet of the etching chamber. If the crystal 601 was not cleaned in time, it would lead to pollution in the inside environment of the apparatus, even scratch the substrate, and affect quality of products in a serious case. However, frequent cleaning will take up a lot of up time of apparatus, thus reducing operation ratio of the apparatus.

In addition, the above-mentioned problem about crystal also exists for other etching liquids which are used in wet etching for the semiconductor related industry and are prone to form crystal (e.g., etching liquids which comprise HNO₃, CH₃COOH, or H₃PO₄ as principal components and are used for etching Al, Mo, Ag, oxide (like ITO, IGZO, etc.), etching liquids which comprise H₂O₂ as a principal component and are used for etching Cu, or the like). Thus, in the wet etching process of the semiconductor related industry, it is a challenge to solve the problem in which an etching liquid which is prone to form crystal will form a lot of crystal during wet etching.

### SUMMARY OF THE INVENTION

### (I) Technical Problem to be Solved

In view of the above-mentioned technical problem, the present invention provides a wet etching apparatus to remove an etching liquid or an etching liquid crystal formed by the etching liquid at an inlet and outlet of the etching chamber, thus improving production efficiency and product quality.

### (II) Technical Solution

The wet etching apparatus in the present invention has the function of removing an etching liquid crystal outside the etching chamber, which comprises: an etching chamber, which comprises an etching chamber inlet at a front end and an etching chamber outlet at a rear end, wherein in the etching chamber, a film to be etched on a substrate is subject to etching with an etching liquid; and a decrystallization device, which washes residual etching liquid or etching liquid crystal formed by the etching liquid at the etching chamber inlet and/or etching chamber outlet with a washing liquid.

### (III) Beneficial Effects

As can be seen from the above-mentioned technical solution, the wet etching apparatus in the present invention has the following beneficial effects.

(1) Since a washing liquid is used to wash residual etching liquid or etching liquid crystal formed by the etching liquid at the etching chamber inlet and the etching chamber outlet, the etching liquid crystal can be effectively prevented from forming at the etching chamber inlet and the etching chamber outlet, and the etching liquid crystal which has been formed at the etching chamber inlet and the etching chamber outlet can be effectively removed. This improves operation ratio and cleanness of the apparatus and quality of products.

(2) The washing liquid supply line can recycle waste water discharged by the wet etching apparatus, so that no additional water resource is consumed, which reduces production cost.

### BRIEF DESCRIPTION OF THE DRAWINGS

FIG. 1 is a structural view of a wet etching apparatus for patterning an ITO film in the prior art;

FIG. 2A is a top view of an etching chamber, a front buffer chamber, and a rear buffer chamber in a wet etching apparatus shown in FIG. 1;

FIG. 2B is a side view of an etching chamber, a front buffer chamber, and a rear buffer chamber in a wet etching apparatus shown in FIG. 1;

FIG. 3 is a schematic view of oxalic acid crystal formed at a shutter in a wet etching apparatus shown in FIG. 1;

FIG. 4A is a schematic view of a wet etching apparatus in a first embodiment of the present invention;

FIG. 4B is a schematic view of a portion of a front buffer chamber close to an etching chamber in a wet etching apparatus shown in FIG. 4A;

FIG. 5 is a schematic view of a wet etching apparatus in a second embodiment of the present invention; and

FIG. 6 is a schematic view of an operating process of a wet etching apparatus shown in FIG. 5.

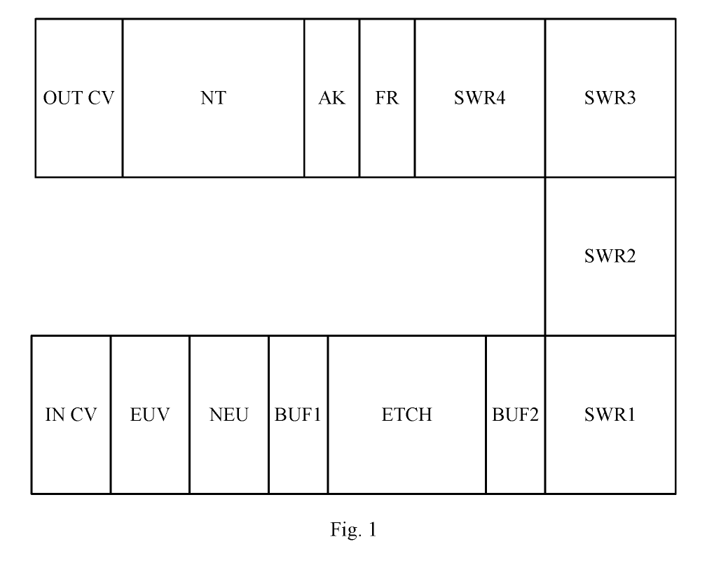

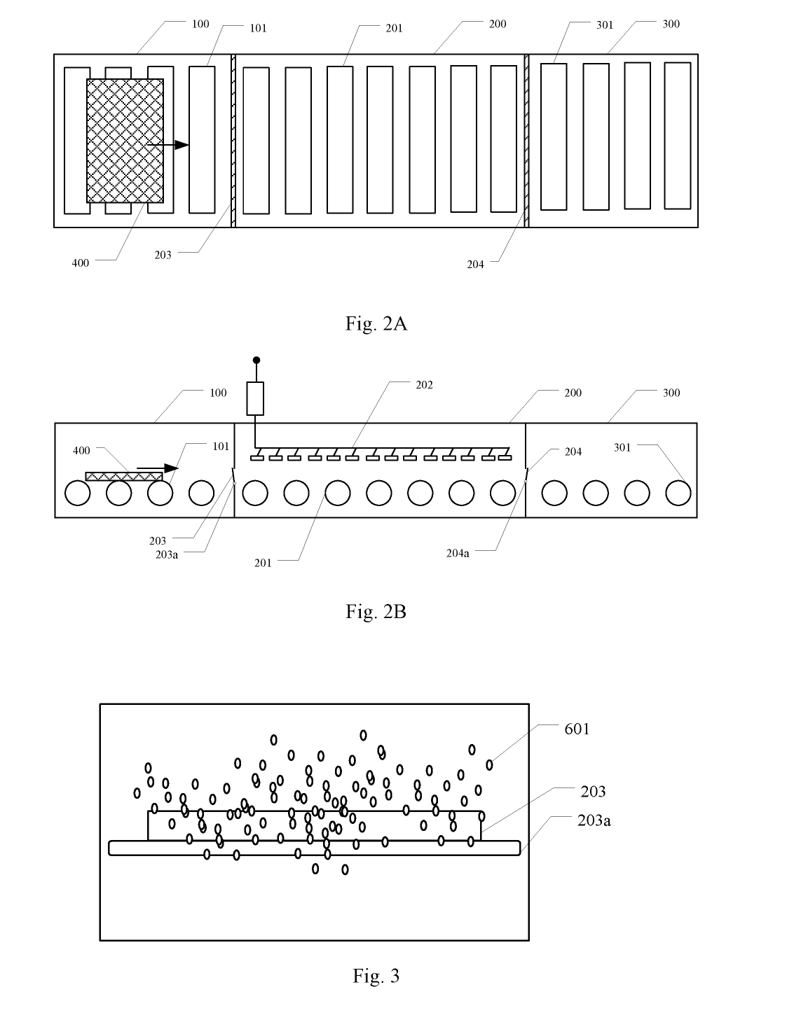

### REFERENCE NUMERALS

IN CV—inlet unit; EUV—washing chamber; NEU—transition unit; BUF1—front buffer chamber; ETCH—etching chamber; BUF2—rear buffer chamber; SWR1—first water rinsing unit; SWR2—second water rinsing unit; SWR3—third water rinsing unit; SWR4—fourth water rinsing unit; FR—final water rinsing unit; AK—air knife unit; NT—transfer unit; OUT CV—outlet unit.
100—front buffer chamber; 101—delivery wheel.
200—etching chamber; 201—delivery wheel; 202—etching liquid spraying device; 203—front shutter; 204—rear shutter; 203a, 204a—shaft.
300—rear buffer chamber; 301—delivery wheel.
400—substrate.
500—decrystallization device; 501—front washing liquid spraying shower; 502—rear washing liquid spraying shower; 501a, 502a—valve; 501b, 502b—pump; 503—washing liquid supply line; 504—water tank.
601—etching liquid crystal.

### DETAILED DESCRIPTION OF THE INVENTION

Embodiments of the present invention make use of the feature that oxalic acid crystal is soluble in water, and provides a washing liquid spraying shower under a shutter at an etching chamber inlet and an etching chamber outlet, so that etching liquid or etching liquid crystal at the etching chamber inlet, the etching chamber outlet, and the shutter can be effectively removed. The present invention will be further described hereinafter by reference to specific embodiments, for the purpose that objects, technical solutions, and advantages of the present invention can be understood clearly.

### First Embodiment

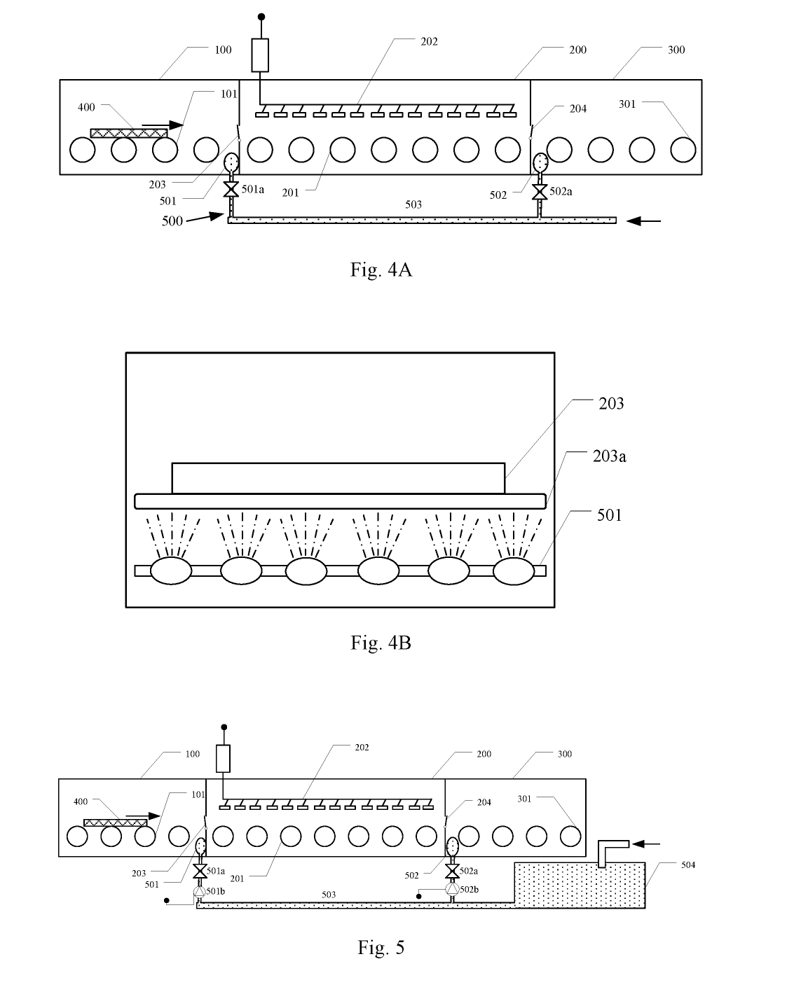

In an exemplary embodiment of the present invention, it is provided a wet etching apparatus. FIG. 4A is a schematic view of a wet etching apparatus in a first embodiment of the present invention. FIG. 4B is a schematic view of a portion of a front buffer chamber close to an etching chamber in a wet etching apparatus shown in FIG. 4A. As shown in FIG. 4A and FIG. 4B, the wet etching apparatus of the present embodiment comprises: a front buffer chamber 100, an etching chamber 200, a rear buffer chamber 300, and a decrystallization device 500. The decrystallization device 500 washes, with a washing liquid, residual etching liquid or etching liquid crystal formed by the etching liquid at an etching chamber inlet and/or etching chamber outlet of the etching chamber 200, to prevent etching liquid crystal from forming at the etching chamber inlet and/or etching chamber outlet, or to remove etching liquid crystal formed at the etching chamber inlet and/or etching chamber outlet. The decrystallization device 500 comprises: a front washing liquid spraying shower 501 which is installed in the front buffer chamber 100 at a position close to the etching chamber 200, a rear washing liquid spraying shower 502 which is installed in the rear buffer chamber 300 at a position close to the etching chamber 200, and a washing liquid supply line 503. The front washing liquid spraying shower 501 and the rear washing liquid spraying shower 502 are supplied with washing liquid by the washing liquid supply line 503, and are used to wash the etching liquid crystal formed at the etching chamber inlet, the etching chamber outlet, and the shutter.

Referring to FIG. 4A, the etching chamber 200 is a principal component in the wet etching apparatus. In the etching chamber 200, an etching liquid spraying device 202 sprays an oxalic acid solution of a predefined concentration to an underlying substrate, and an ITO film on the substrate which is noted covered by photoresist is removed.

The front buffer chamber 100 and the rear buffer chamber 300 are connected with a front end and a rear end of the etching chamber 200 respectively, and communicate with the etching chamber 200 through the etching chamber inlet and the etching chamber outlet, respectively. Continuous delivery wheels 101, 201, 301 are installed in a transport path. Under driving of the delivery wheels, the substrate 400 leaves the front buffer chamber 100, enters the etching chamber 200 through the etching chamber inlet for etching, leaves the etching chamber 200 through the etching chamber outlet, and is transferred to the rear buffer chamber 300.

A front shutter 203 is installed in the front buffer chamber 100 at a position close to the etching chamber inlet. The front shutter 203 is installed at a lower portion of the etching chamber inlet by means of a shaft 203a. Before the substrate 400 enters the etching chamber 200, the front shutter 203 is folded by 90° towards the front buffer chamber 100, and the etching chamber inlet is opened. The substrate 400 enters the etching chamber 200 through the etching chamber inlet. After the substrate 400 completely enters the etching chamber 200, the front shutter 203 is folded by 90° towards the etching chamber 200, so that the etching chamber inlet is closed, to ensure a relatively closed environment in the etching chamber 200.

In the same way, a rear shutter 204 is installed in the rear buffer chamber at a position close to the etching chamber outlet. The rear shutter 204 is installed at a lower portion of the etching chamber outlet by means of a shaft. Before the substrate 400 enters the rear buffer chamber 300, the rear shutter 204 is folded by 90° towards the rear buffer chamber 300, and the etching chamber outlet is opened. The substrate 400 enters the rear buffer chamber 300 through the etching chamber outlet. After the substrate 400 completely enters the rear buffer chamber 300, the rear shutter 204 is folded by 90° towards the etching chamber 200, so that the etching chamber outlet is closed, to ensure a relatively closed environment in the etching chamber 200.

Referring to FIG. 4A and FIG. 4B, in the front buffer chamber 100, a front washing liquid spraying shower 501 is installed at a lower portion of the front shutter 203. In the rear buffer chamber 300, the rear washing liquid spraying shower 502 is installed at a lower portion of the rear shutter 204. The front washing liquid spraying shower 501 and the rear washing liquid spraying shower 502 are supplied with washing liquid by the washing liquid supply line 503, and spray water columns to wash corresponding portions of the shutter in a folded state, so that the oxalic acid is removed prior to its formation into crystal. Namely, in this embodiment, water is used as the washing liquid to remove the etching liquid from the shutter prior to the etching liquid's formation into crystal. As a result, the etching liquid is prevented from forming the etching liquid crystal on the shutter.

In this embodiment, both the front washing liquid spraying shower 501 and the rear washing liquid spraying shower 502 comprise: a washing liquid spraying shower body and holes which are arranged in the washing liquid spraying shower body and oriented upwards. The holes have an aperture size which is generally 2˜5 mm. Herein, as compared with a nozzle water sprayed from which easily spatters on the substrate, it is preferred in the present invention to adopt the washing liquid spraying shower with holes to spray the washing liquid.

It is noted that, the holes in the front washing liquid spraying shower 501 and the rear washing liquid spraying shower 502 spray water column of such a height that is just enough to wash the shutter which is folded downwards. If the water column is too high, water drops may spatter on the substrate, which influences the concentration of oxalic acid etching liquid, and results in drawbacks like etching residual, mura (chromatic aberration due to non-uniform etching). If the water column is too low, the effect of removing etching liquid or its crystal may be affected.

Referring to FIG. 4A, two ends of the front washing liquid spraying shower 501 and the rear washing liquid spraying shower 502 are sealed, and middle portions are connected with the washing liquid supply line 503 through a valve 501a and a valve 502a. The valves (501a, 502a) are used to adjust water pressure in the washing liquid spraying shower, thus to control the height of water column sprayed from holes in the washing liquid spraying shower. After washing, the waste water can be discharged through waste water discharge lines of the front and rear buffer chambers. The washing liquid supply line 503 communicates with a factory pure water line.

It is noted that in the present embodiment as well as the following embodiments, the decrystallization device is arranged in both the front buffer chamber and the rear buffer chamber. However, the present invention is not limited to this. In the present invention, the decrystallization device can only be arranged in one of the front buffer chamber and the rear buffer chamber, and this also falls within the protection scope of the present invention.

In addition, in the present embodiment as well as the following embodiments, the front washing liquid spraying shower and the rear washing liquid spraying shower are supplied with water in a central manner. However, the present invention is not limited to this. The front washing liquid spraying shower and the rear washing liquid spraying shower can further be supplied with water in a separate manner.

The wet etching apparatus of the present embodiment has the following advantages. The washing liquid spraying shower continuously washes etching liquid crystal at the etching chamber inlet, the etching chamber outlet, and the shutter, so that an excellent effect in removing crystal is obtained and the design cost is low. The disadvantage lies in that the washing liquid spraying shower stays in a washing state, which may waste water resource.

### Second Embodiment

In another embodiment of the present invention, it is further provided another wet etching apparatus. FIG. 5 is a schematic view of a wet etching apparatus in a second embodiment of the present invention. Referring to FIG. 4A and FIG. 5, the wet etching apparatus of the present embodiment differs from that of the first embodiment in the manner for supplying washing liquid to the washing liquid supply line.

As shown in FIG. 5, in the wet etching apparatus of the present embodiment, the decrystallization device 500 further comprises a water tank 504 and two pumps 501b, 502b. The washing liquid supply line 503 is connected to the water tank 504, and water in the water tank 504 is supplied by a factory pure water line. The pump 501b is arranged between the washing liquid supply line 503 and the front washing liquid spraying shower 501. The pump 502b is arranged between the washing liquid supply line 503 and the rear washing liquid spraying shower 502.

The front washing liquid spraying shower 501 is connected to the washing liquid supply line 503 through the pump 501b. A control signal for the pump 501b is synchronous with that for a cylinder of the front shutter. Namely, when the front shutter 203 is opened (i.e., folded towards the front buffer chamber), the pump 501b is started, and the front washing liquid spraying shower 501 sprays water to the front shutter 203 for washing; while when the front shutter 203 is closed (i.e., folded towards the etching chamber), the pump 501b is shut, and the front washing liquid spraying shower stops spraying water.

Similarly, the rear washing liquid spraying shower 502 is connected to the washing liquid supply line 503 through the pump 502b, and a control signal of the pump 502b is synchronous with that for a cylinder of the rear shutter, which is not repeated for simplicity.

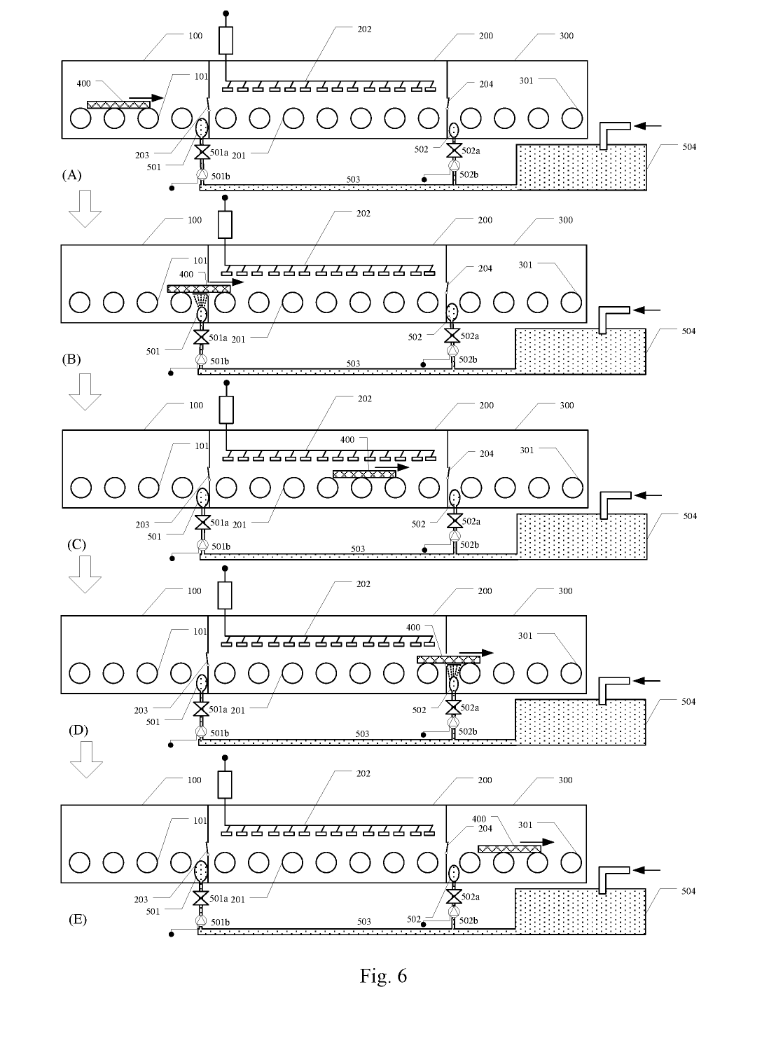

FIG. 6 is a schematic view of an operating process of a wet etching apparatus shown in FIG. 5. Referring to FIG. 6, an operating process of the wet etching apparatus of the present embodiment will be described by reference to the following steps A-E.

Step A: under actuation of delivery wheels in the transport path, the substrate 400 in the front buffer chamber is moved towards the etching chamber 200, as shown by A in FIG. 6.

Step B: Before the substrate 400 enters the etching chamber 200, the front shutter 203 is folded by 90° towards front buffer chamber to open the etching chamber inlet. At the same time, the pump 501b is started, and the front washing liquid spraying shower 501 sprays water to the front shutter 203, to wash the etching liquid crystal at the etching chamber inlet and the front shutter 203. The water is sprayed to a height which is determined by the valve 501a, as shown by B in FIG. 6.

Step C: after the substrate 400 completely enters the etching chamber 200, the front shutter 203 is folded towards the etching chamber, and the etching chamber inlet is closed. At the same time, the pump 501b is shut simultaneously, as shown by C in FIG. 6.

Step D: before the substrate 400 is close to the rear buffer chamber 300, the rear shutter 204 is folded by 90° towards rear buffer chamber, so that the etching chamber outlet is opened, and the substrate 400 enters the rear buffer chamber 300 through the etching chamber outlet. At the same time, the pump 502b is started, and the rear washing liquid spraying shower 502 sprays water to the rear shutter 204, to wash the etching liquid crystal at the etching chamber outlet and the rear shutter 204. The water is sprayed to a height which is determined by the valve 502a, as shown by D in FIG. 6.

Step E: after the substrate 400 completely enters the rear buffer chamber 300, the rear shutter 204 is folded towards the etching chamber 200, so that the etching chamber outlet is closed, and the pump 502b is shut simultaneously, as shown by E in FIG. 6.

The wet etching apparatus of the present embodiment has the following advantages. Only when the substrate enters/leaves the etching chamber, the washing liquid spraying device washes the etching liquid crystal at the etching chamber inlet (outlet) and the corresponding shutter. In this way, the effect of removing crystal is excellent, and water resource is saved. The disadvantages lie in that the structure is relatively complex and the design cost is relatively high.

### Third Embodiment

In another embodiment of the present invention, it is further provided another wet etching apparatus. The wet etching apparatus of the present embodiment differs from that of the second embodiment in that the water tank is supplied with water by a line which is derived from the waste water discharge line in a first water rinsing unit SWR1 of the wet etching apparatus. The flux of washing water in the first water rinsing unit SWR1 is relative large, which can completely meet the requirement of this decrystallization device for the flux of water for removing oxalic acid crystal, and the redundant water flux can be discharged from a top of the water tank.

The wet etching apparatus of the present embodiment has a similar operating principle with that of the second embodiment, which is not repeated for simplicity.

Generally, the waste water from the first water rinsing unit SWR1 is directly discharged. The present embodiment has the advantages that an excellent effect in removing crystal is obtained, waste water discharged by the wet etching apparatus is recycled, no water resource is consumed, and the production cost is reduced. The disadvantage lies in that the structure is relatively complex and the design is relatively high.

From the long-term benefits, the third embodiment is the most preferred.

It is noted that the above three embodiments have been described in case oxalic acid etching solution is used to etch an ITO film. However, the present invention is not limited to this. The etching liquid can further be other etching liquids which are prone to form crystal, e.g., an etching liquid which comprises HNO₃, CH₃COOH, or H₃PO₄ as principal components and is used for etching Al, Mo, Ag, oxide (e.g., ITO, IGZO, or the like), an etching liquid which comprises H₂O₂ as a principal component and is used for etching Cu, or the like. In this case, pure water can be used as the washing liquid to wash the etching liquid crystal. Besides, other liquids can be used, or an effect-increasing component like NaOH, KOH or the like can be added into pure water, to form a washing liquid for washing the etching liquid crystal. Namely, in embodiments of the present invention, the washing liquid can be pure water, or an aqueous solution of NaOH, KOH. Of course, the washing liquid can further be any suitable alkaline solution comprising components which are determined by the etching liquid adopted in the wet etching apparatus.

In addition, other chambers than the front buffer chamber can be arranged at a front end of the etching chamber. Similarly, other chambers than the rear buffer chamber can be arranged at a rear end of the etching chamber, and this is also applicable to the present invention.

To this end, three embodiments of the present invention have been described in details with reference to the accompanying drawings. On basis of the foregoing description, the wet etching apparatus in the present invention will be clear for a skilled in the art.

In addition, the above definitions of each element and method are not limited to the specific structure, shape or manner mentioned in these embodiments, and an ordinary skilled in the art can make simple change or replacement. For example, other types of shutters than the foldable type of shutter in the above-mentioned embodiment are applicable to the present invention. In addition, the shutter can be folded to an angle which is modified as required, and is not strictly limited the above-mentioned 90°.

To sum up, in the present invention, a washing liquid spraying shower is arranged at the etching chamber inlet and the etching chamber outlet of the etching chamber, so that the large amount of etching liquid crystal at the etching chamber inlet and the etching chamber outlet can be effectively removed at a low cost, and operation ratio, cleanness and product quality of the apparatus is improved. The present invention has a high value for popularization and application.

It is noted that similar or identical portions are labeled with identical numerals throughout the drawings and description. Details which are known for the ordinary skilled in the art are not illustrated or described in the drawings. Furthermore, although exemplary parameters provided herein may contain a specific value, it should be understood that the parameters do not need to exactly equal to the corresponding value, but may be similar to the corresponding tolerance values or design constraints within an acceptable error. Orientational terms mentioned in embodiments like “upper”, “lower”, “front”, “rear”, “left”, “right”, etc., only indicate a direction with respect to the accompanying drawings. Thus, the orientational terms used in this description is not intended to limit the scope of the present invention.

Although the present invention has been described above with reference to specific embodiments, it should be understood that the limitations of the described embodiments are merely for illustrative purpose and by no means limiting. Instead, the scope of the invention is defined by the appended claims rather than by the description, and all variations that fall within the range of the claims are intended to be embraced therein. Thus, other embodiments than the specific ones described above are equally possible within the scope of these appended claims.

1. A wet etching apparatus, comprising:
an etching chamber, comprising an etching chamber inlet at a front end and an etching chamber outlet at a rear end, wherein in the etching chamber, a film to be etched on a substrate is subject to etching with an etching liquid; and
a decrystallization device, which washes residual etching liquid or etching liquid crystal formed by the etching liquid at the etching chamber inlet and/or etching chamber outlet with a washing liquid.

2. The wet etching apparatus of claim 1, wherein the decrystallization device comprises:
a washing liquid spraying shower, which is arranged under the etching chamber inlet and/or etching chamber outlet, and adapted to eject upwards the washing liquid, to wash the residual etching liquid or etching liquid crystal formed by the etching liquid at the etching chamber inlet and/or etching chamber outlet.

3. The wet etching apparatus of claim 2, further comprising:
a neighboring chamber, which is connected with the front end or the rear end of the etching chamber; and
a shutter, which is installed at the etching chamber inlet or the etching chamber outlet by means of a shaft, which is opened when the substrate is passing and closed in other times,
wherein the washing liquid spraying shower is arranged under the shutter in an opened state, to wash the etching liquid or etching liquid crystal formed by the etching liquid on the shutter.

4. The wet etching apparatus of claim 3, wherein in a closed state, the shutter is perpendicular to a traveling direction of the substrate, and the etching chamber inlet and/or etching chamber outlet of the etching chamber is closed; and
in the opened state, the shutter is folded towards the neighboring chamber, and the etching chamber inlet and/or etching chamber outlet of the etching chamber is opened.

5. The wet etching apparatus of claim 4, wherein the washing liquid spraying shower ejects upwards the washing liquid to a height in flush with the shutter in the opened state.

6. The wet etching apparatus of claim 4, wherein the washing liquid spraying shower continuously ejects upwards the washing liquid.

7. The wet etching apparatus of claim 4, wherein
when the shutter is in the opened state, the washing liquid spraying shower eject upwards the washing liquid; and
when the shutter is in the closed state, the washing liquid spraying shower stops ejecting upwards the washing liquid.

8. The wet etching apparatus of claim 2, wherein the washing liquid spraying shower comprises:
a washing liquid spraying shower body; and
groups of holes, which are arranged in the washing liquid spraying shower body and orientated upwards to the shutter.

9. The wet etching apparatus of claim 8, wherein the holes have an aperture size of 2 mm-5 mm.

10. The wet etching apparatus of claim 3, wherein the neighboring chamber comprises a front buffer chamber which communicates with the etching chamber through a front shutter and a rear buffer chamber which communicates with the etching chamber through a rear shutter; and
the washing liquid spraying shower comprises a front washing liquid spraying shower which is installed in the front buffer chamber and located under the front shutter, and a rear washing liquid spraying shower which is installed in the rear buffer chamber and located under the rear shutter.

11. The wet etching apparatus of claim 1, wherein the etching liquid is an acid etching liquid which is prone to form crystal, and the washing liquid is pure water or alkaline washing liquid.

12. The wet etching apparatus of claim 11, wherein the acid etching liquid is oxalic acid solution, HNO₃ solution, CH₃COOH solution or H₃PO₄ solution, and the alkaline washing liquid is an aqueous solution of NaOH, KOH.

13. The wet etching apparatus of claim 2, wherein the decrystallization device further comprises:
a washing liquid supply line, which supplies washing liquid to the washing liquid spraying shower; and
a valve, which is arranged between the washing liquid supply line and the washing liquid spraying shower, and adjusts pressure in the washing liquid supply line to control a height to which the washing liquid is ejected.

14. The wet etching apparatus of claim 13, wherein a pump is arranged between the washing liquid supply line and the washing liquid spraying shower, and a control signal for the pump is synchronous with that for the shutter.

15. The wet etching apparatus of claim 14, wherein when the shutter is opened, the pump is started simultaneously, and the washing liquid supply line starts to supply the washing liquid to the washing liquid spraying shower; and
when the shutter is closed, the pump is shut simultaneously, and the washing liquid supply line stops supplying the washing liquid to the washing liquid spraying shower.

16. The wet etching apparatus of claim 13, wherein the washing liquid supply line is connected to a factory pure water line.

17. The wet etching apparatus of claim 13, wherein the washing liquid supply line is connected to a water tank, which is supplied with water by a factory pure water line or by waste water discharged from a water rinsing unit of the wet etching apparatus.
